(19) United States
(12) Patent Application Publication
(10) Pub. No.: US 2024/0040835 A1
(43) Pub. Date: Feb. 1, 2024

(54) DISPLAY PANEL AND DISPLAY DEVICE INCLUDING THE SAME

(71) Applicant: LG DISPLAY CO., LTD., SEOUL (KR)

(72) Inventors: Seung Han PAEK, Paju-si (KR); Yong Min HA, Paju-si (KR); Yong In PARK, Paju-si (KR); Eui Hyun CHUNG, Paju-si (KR)

(73) Assignee: LG DISPLAY CO., LTD., SEOUL (KR)

(21) Appl. No.: 18/224,962

(22) Filed: Jul. 21, 2023

(30) Foreign Application Priority Data
Jul. 29, 2022 (KR) 10-2022-0094663

(51) Int. Cl. H10K 59/121; H10K 59/122

(52) U.S. Cl. CPC H10K 59/1213; H10K 59/122

(57) ABSTRACT

Embodiments disclose a display panel including a glass substrate including a display area and a light-transmitting area, a circuit portion disposed in the display area, and a light emitting portion disposed on the circuit portion, wherein the glass substrate includes a first opening disposed at a position corresponding to the light-transmitting area, and the display panel includes a first etch-stop layer disposed on the glass substrate and surrounding the first opening, and a display device including the same.

### CROSS-REFERENCE TO RELATED APPLICATIONS

This application claims priority to and the benefit of Korean Patent Application No. filed on Jul. 29, 2022, the disclosure of which is incorporated herein by reference in its entirety.

### BACKGROUND

### 1. Field of the Disclosure

Embodiments relate to a display panel and a display device including the same.

### 2. Discussion of Related Art

Electroluminescence display devices are roughly classified into inorganic light-emitting display devices and organic light-emitting display devices depending on materials of an emission layer. An active-matrix type organic light-emitting display device includes an organic light-emitting diode (OLED) that emits light by itself and has advantages in terms of a quick response time, high luminous efficiency, high luminance, and a wide viewing angle. The organic light-emitting display device has OLEDs formed in each pixel. The organic light-emitting display device may represent a black grayscale as perfect black as well as having a quick response time, high luminous efficiency, high luminance, and a wide viewing angle, and thus has an excellent contrast ratio and color gamut.

Recently, organic light-emitting display devices are being implemented on plastic substrates, which are flexible materials, but may also be implemented on glass substrates due to various issues.

However, when the organic light-emitting display devices are implemented on the glass substrates, there is a problem that rigidity is reduced when processing notches or recesses or forming holes in a panel and it is difficult to process various shapes.

### SUMMARY

Embodiments provide a display panel that maintains rigidity while processing a glass substrate and forming holes of various shapes, and a display device including the same.

It should be noted that objects of the present disclosure are not limited to the above-described object, and other objects of the present disclosure will be apparent to those skilled in the art from the following descriptions.

A display panel according to one feature of the present disclosure includes a glass substrate including a display area and a light-transmitting area, a circuit portion disposed in the display area, and an element portion disposed on the circuit portion, wherein the glass substrate includes a first opening disposed at a position corresponding to the light-transmitting area, and the display panel includes a first etch-stop layer disposed on the glass substrate and surrounding the first opening.

A display panel according to another feature of the present disclosure includes a glass substrate including a display area and a light-transmitting area, a circuit portion disposed in the display area, and an element portion disposed on the circuit portion, wherein the glass substrate includes a first opening disposed at a position corresponding to the light-transmitting area and a second inclined surface formed on a side surface thereof, wherein an inclination angle of an inner side surface of the first opening and an inclination angle of the second inclined surface are the same.

### BRIEF DESCRIPTION OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a conceptual diagram of a display device according to one aspect of the present disclosure;

FIG. 2 is a cross-sectional view taken along line I-I′ of FIG. 1;

FIG. 3 is an enlarged view of portion A of FIG. 2;

FIG. 4 is an enlarged view of portion B of FIG. 2;

FIG. 5A is a modified example of FIG. 3;

FIG. 5B is a modified example of FIG. 4;

FIG. 6 is a view illustrating an etch-stop layer surrounding a light-transmitting area and an edge area of a substrate;

FIGS. 7A to 7D are views illustrating openings of various shapes of the substrate;

FIG. 8 is a view illustrating a cross section of a display area;

FIG. 9 is a view illustrating a display panel according to a first aspect of the present disclosure;

FIG. 10 is a view illustrating the display panel before forming a light-transmitting area;

FIGS. 11A to 11C are views illustrating a process of etching a substrate to form the light-transmitting area in the display panel;

FIG. 11D is a view illustrating a shape in which a first opening is entirely filled with a coating layer;

FIGS. 12A and 12B are views illustrating etch-stop layers of various structures;

FIG. 13 is a view illustrating a display panel according to a second aspect of the present disclosure;

FIGS. 14A to 14C are views illustrating a process of etching a substrate to form a light-transmitting area in the display panel;

FIG. 15 is a view illustrating a display panel according to a third aspect of the present disclosure;

FIG. 16 is a view illustrating the display panel before forming a light-transmitting area;

FIGS. 17A to 17C are views illustrating a process of forming an etch-stop layer in a dummy area;

FIGS. 18A and 18B are views illustrating a process of etching a substrate to form the light-transmitting area in the display panel;

FIG. 19 is a modified example of FIG. 18A; and

FIG. 20 is a conceptual diagram of a display device according to another aspect of the present disclosure.

### DETAILED DESCRIPTION

Advantages and features of the present disclosure and implementation methods thereof will be clarified through the following embodiments described with reference to the accompanying drawings. However, the present disclosure is not limited to the embodiments described below and may be implemented with a variety of different forms. The embodiments are merely provided to allow those skilled in the art to completely understand the scope of the present disclosure, and the present disclosure is defined only by the scope of the claims.

The figures, dimensions, ratios, angles, numbers, and the like disclosed in the drawings for describing the embodiments of the present disclosure are merely illustrative and are not limited to matters shown in the present disclosure. Throughout the specification, like reference numerals refer to like elements. Further, in describing the present disclosure, detailed descriptions of well-known technologies will be omitted when it is determined that they may unnecessarily obscure the gist of the present disclosure.

Terms such as “including,” “having,” and “composed of” used herein are intended to allow other elements to be added unless the terms are used with the term “only.” Any references to the singular may include the plural unless expressly stated otherwise.

Components are interpreted to include an ordinary error range even if not expressly stated.

For description of a positional relationship, for example, when the positional relationship between two parts is described as “on,” “above,” “below,” and “next to,” etc., one or more parts may be interposed therebetween unless the term “immediately” or “directly” is used in the expression.

In the description of embodiments, the terms “first,” “second,” and the like may be used herein to describe various elements, the elements are not limited by the terms. These terms are used only to distinguish one component from another. Therefore, a first component discussed below could be termed a second component without departing from the teachings of the present disclosure.

Throughout the specification, like reference numerals refer to like elements.

The features of various embodiments may be partially or entirely bonded to or combined with each other. The embodiments may be interoperated and performed in technically various ways and may be carried out independently of or in association with each other.

Hereinafter, various aspects of the present disclosure will be described in detail with reference to the accompanying drawings.

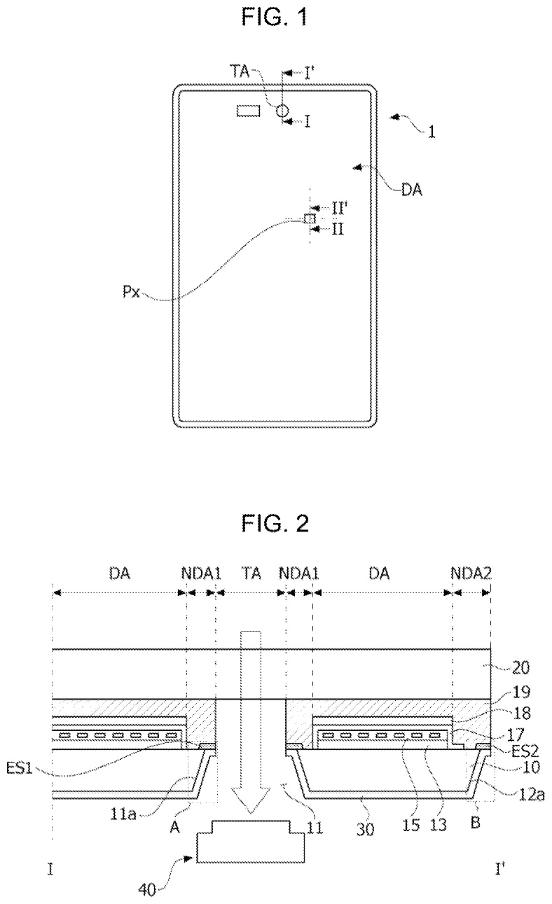

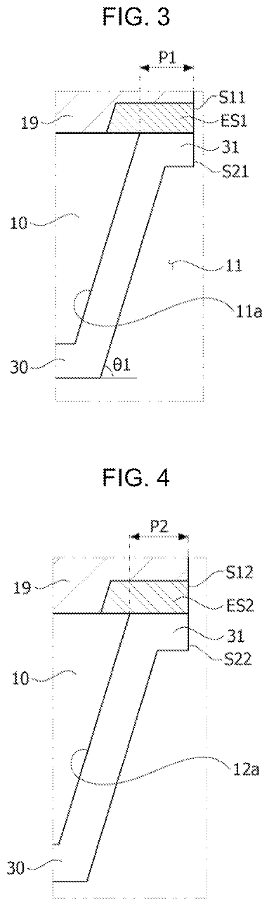

FIG. 1 is a conceptual diagram of a display device according to one aspect of the present disclosure. FIG. 2 is a cross-sectional view taken along line I-I′ of FIG. 1. FIG. 3 is an enlarged view of portion A of FIG. 2. FIG. 4 is an enlarged view of portion B of FIG. 2;

Referring to FIGS. 1 and 2, a display device 1 may include a display area DA from which an image is output and a light-transmitting area TA through which light is incident. The light-transmitting area TA may have a hole structure for allowing light to be incident on sensors disposed below a display panel, but the present disclosure is not necessarily limited thereto.

The display panel may include a circuit portion 13 disposed on a substrate 10, and an element portion (light emitting portion) 15 disposed on the circuit portion 13. A polarizing plate 19 may be disposed on the element portion 15, and a cover glass 20 may be disposed on the polarizing plate 19. In addition, a touch portion 18 may be disposed between the element portion 15 and the polarizing plate 19.

According to the aspect, the substrate 10 may include a glass material. That is, the substrate according to the aspect may have a predetermined strength. However, the substrate is not necessarily limited thereto, may also include a flexible material such as polyimide.

The circuit portion 13 may include a pixel circuit connected to wirings such as data lines, gate lines, and power lines, a gate driving portion connected to the gate lines, and the like.

The circuit portion 13 may include circuit elements such as a transistor implemented as a thin-film transistor (TFT), a capacitor, and the like. The wirings and circuit elements of the circuit portion 13 may be implemented with a plurality of insulating layers, two or more metal layers separated from each other with the insulating layer therebetween, and an active layer including a semiconductor material.

The element portion 15 may have element structures such as an organic light-emitting diode (OLED) display, a quantum dot display, a micro light-emitting diode (LED) display, and the like. Hereinafter, an OLED structure including an organic compound layer will be described as an example.

The organic compound layer may include a hole injection layer HIL, a hole transport layer HTL, an emission layer EML, an electron transport layer ETL, and an electron injection layer EIL, but the present disclosure is not limited thereto.

When a voltage is applied to an anode and a cathode of an OLED, holes passing through the hole transport layer HTL and electrons passing through the electron transport layer ETL move to the emission layer EML to create excitons and emit visible light from the emission layer EML.

The element portion 15 may further include a color filter array that is disposed on pixels Px and selectively transmits light of red, green, and blue wavelengths.

The element portion 15 may be covered by a protective film, and the protective film may be covered by an encapsulation portion 17. The protective film and the encapsulation portion 17 may alternatively stack an organic film and an inorganic film. The inorganic film may block the penetration of moisture or oxygen. The organic film may planarize a surface of the inorganic film. Thus, when the organic and inorganic films are stacked in multiple layers, a path of the moisture or oxygen is longer as compared to a single layer, and the penetration of moisture/oxygen affecting the element portion 15 may be effectively blocked.

The polarizing plate 19 may be disposed on the element portion 15. The polarizing plate 19 may improve outdoor visibility of the display device. The polarizing plate 19 may reduce light reflected from a surface of the display panel and block light reflected from the metal of the circuit portion 13 to improve the brightness of the pixels Px. The polarizing plate 19 may be implemented as a polarizing plate to which a linear polarizing plate 19 and a phase retardation film are bonded, or may be implemented as a circular polarizing plate.

The light-transmitting area TA may be formed between the display areas DA. A first non-display area NDA1 may be disposed to surround the light-transmitting area TA. The first non-display area NDA1 may include a plurality of dam structures to protect light-emitting elements of the display area DA from moisture or oxygen that may be introduced from the light-transmitting area TA.

The light-transmitting area TA may have a through-hole structure for injecting light into an image-capturing unit such as a camera. However, the present disclosure is not necessarily limited thereto, and pixels having a low density may be disposed in the light-transmitting area TA.

The substrate 10 may include a first opening 11 disposed in the light-transmitting area TA. The first opening 11 may have a tapered shape that narrows in width as it approaches the cover glass 20. However, the first opening 11 is not necessarily limited thereto, and may have a reverse tapered shape that increases in width as it approaches the cover glass 20 or may be constant in width in a thickness direction. The tapered shape of the first opening 11 may be variously changed by the type of an etchant and an etching method.

Referring to FIG. 2, a first etch-stop layer ES1 may be disposed on the first opening 11 of the substrate 10. In addition, a second etch-stop layer ES2 may be disposed on an edge of the substrate 10. The first etch-stop layer ES1 and the second etch-stop layer ES2 may prevent an etchant from penetrating into the panel when etching the substrate 10.

The first etch-stop layer ES1 and the second etch-stop layer ES2 may include an organic material that is resistant to an etchant. As an example, the etch-stop layer may include one selected from the group consisting of a polyester-based polymer, a silicone-based polymer, an acrylic-based polymer, a polyolefin-based polymer, and a copolymer thereof. However, the etch-stop layer is not necessarily limited thereto and may include various materials that are resistant to the etchant.

The first etch-stop layer ES1 and the second etch-stop layer ES2 may be formed by extending from at least one of the layers constituting the circuit portion 13, the element portion the encapsulation portion 17, and the touch portion 18. That is, the first etch-stop layer ES1 and the second etch-stop layer ES2 may be dummy layers extending from the circuit portion 13, the element portion 15, the encapsulation portion 17, or the touch portion 18. Based on this configuration, the etch-stop layer may be formed without adding a separate process.

According to the aspect, the first etch-stop layer ES1 may include a protrusion P1 protruding toward an inner side of the first opening 11. The protrusion P1 may protrude more toward the inner side of the first opening 11 than an upper surface of the first opening 11. The protrusion P1 may be formed during a process of laser cutting the etch-stop layer.

A coating layer 30 may be formed on a rear surface of the substrate 10. The coating layer 30 may be formed of an organic material including, for example, a polyester-based polymer or an acrylic-based polymer.

A portion of the coating layer 30 may be formed on an inner side surface of the first opening 11. In this case, the portion of the coating layer 30 may be disposed to a lower surface of the protrusion P1 of the first etch-stop layer ES1. That is, the protrusion P1 of the first etch-stop layer ES1 may be disposed on an upper surface of the coating layer 30 formed in the first opening 11.

A first inclined surface 11a of the first opening 11 and a side surface S11 of the protrusion P1 of the first etch-stop layer may have different inclinations. As an example, an inclination angle of the side surface S11 of the protrusion P1 may be greater than an inclination angle θ1 of the first inclined surface 11a. This is because the first opening 11 is etched by an etchant and has a tapered shape, while the first etch-stop layer ES1 is cut by a laser to form a relatively vertical cross section. A side surface S21 of an end portion 31 of the coating layer disposed below the protrusion P1 may have the same inclination angle as the side surface S11 of the protrusion P1.

However, the present disclosure is not necessarily limited thereto, and the first inclined surface 1 la may have a greater inclination than a side surface of the first etch-stop layer ES1 when the first opening 11 has a reverse tapered shape that increases in width as it approaches the cover glass 20.

Referring to FIGS. 2 and 4, a second non-display area NDA2 may be disposed at an edge of the display panel. The second non-display area NDA2 may be a margin region required to separate a plurality of panels from a mother substrate.

The substrate 10 may include a second inclined surface 12a formed at the edge thereof. The second inclined surface 12a may have the same angle and the same depth as the first inclined surface 11 a formed in the first opening 11. The first opening 11 and the second inclined surface 12a are formed simultaneously by an etchant, so that the first opening 11 and the second inclined surface 12a may have the same inclination angle and etching depth.

According to the aspect, the first opening 11 may be formed in a substrate of each display panel concurrently while separating a plurality of display panels by etching a mother substrate using an etchant. Accordingly, the opening may be formed without additional equipment and without reducing rigidity. In addition, various shapes of openings may be formed by changing a mask pattern.

The second etch-stop layer ES2 disposed in the second non-display area NDA2 may prevent an etchant from penetrating into a plurality of display panels when etching a mother substrate to separate the plurality of display panels.

The second etch-stop layer ES2 may extend from at least one of the layers of the circuit portion 13, the element portion 15, the encapsulation portion 17, and the touch portion 18. Alternatively, the second etch-stop layer may be formed simultaneously while forming at least one of the layers of the circuit portion 13, the element portion 15, the encapsulation portion 17, and the touch portion 18. Based on this configuration, the second etch-stop layer ES2 may be formed without adding a separate process.

According to the aspect, the second etch-stop layer ES2 may include a protrusion P2 protruding outwardly from the second inclined surface 12a. The protrusion P2 may prevent damage to the display panel when laser cutting the second etch-stop layer ES2.

The coating layer 30 may be formed on the second inclined surface 12a. At this time, a portion of the coating layer 30 may extend to a lower surface of the protrusion P2.

The second inclined surface 12a of the substrate 10 and a side surface S12 of the protrusion P2 of the second etch-stop layer ES2 may have different inclinations. As an example, an inclination angle of the side surface S12 of the protrusion P2 may be greater than an inclination angle of the second inclined surface 12a. This is because the second inclined surface 12a is etched by an etchant and has a tapered shape, while the second etch-stop layer ES2 is formed by laser cutting the side surface S12. A side surface S22 of the end portion 31 of the coating layer 30 disposed below the protrusion P2 may have the same inclination angle as the side surface S12 of the protrusion P2.

However, the present disclosure is not necessarily limited thereto, and when the second inclined surface 12a has a reverse tapered shape, the second inclined surface 12a has a greater inclination than the second etch-stop layer ES2.

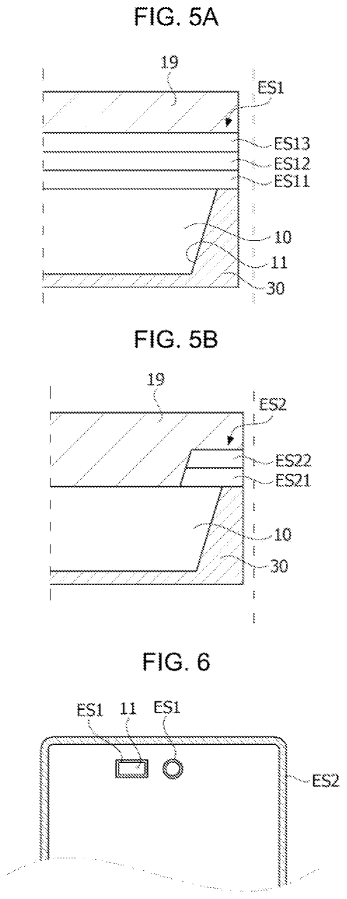

Referring to FIG. 5A, the first etch-stop layer ES1 may include first to third sub-layers ES11, ES12, and ES13. The first sub-layer ES11 may be an inorganic film, and the third sub-layer ES13 may be an organic film. Since an adhesive force between the organic film and the glass substrate 10 is relatively weak, the adhesive force between the organic film and the substrate 10 may be improved by the inorganic film.

In some cases, the second sub-layer ES12 may be a metal layer. The second sub-layer ES12 may include molybdenum (Mo) or the like, which has relatively greater chemical resistance to an etchant as compared to the first sub-layer ES11. However, the present disclosure is not necessarily limited thereto, and the second sub-layer ES12 may be omitted as necessary.

The first opening 11 may be entirely filled with the coating layer 30. Accordingly, when the first etch-stop layer ES1 is cut by a laser, the coating layer 30 formed in the first opening 11 may be cut to have the same cross section as the first etch-stop layer ES1. Thus, the cross section of the first etch-stop layer ES1 and the cross section of the coating layer 30 formed in the first opening 11 may be coplanar with each other.

Referring to FIG. 5B, the second etch-stop layer ES2 may include a first sub-layer ES21 and a second sub-layer ES22. The first sub-layer ES21 may be an inorganic film, and the second sub-layer ES22 may be an organic film. However, the present disclosure is not necessarily limited thereto, and the second etch-stop layer may have the structure as shown in FIG. 5A.

The first etch-stop layer ES1 and the second etch-stop layer ES2 may have the same layer structure or different layer structures. As an example, some layers of the display area DA may be extendable to the first non-display area NDA1 but may be difficult to extend to the second non-display area NDA2. In this case, the first etch-stop layer ES1 and the second etch-stop layer ES2 may have different layer structures.

In addition, the first etch-stop layer ES1 may be formed by continuously extending from the display area DA, while the second etch-stop layer ES2 may be formed to be disconnected from the display area DA. Alternatively, in contrast thereto, the second etch-stop layer ES2 may be formed to extend from the display area DA, while the first etch-stop layer ES1 may be formed to be disconnected from the display area DA.

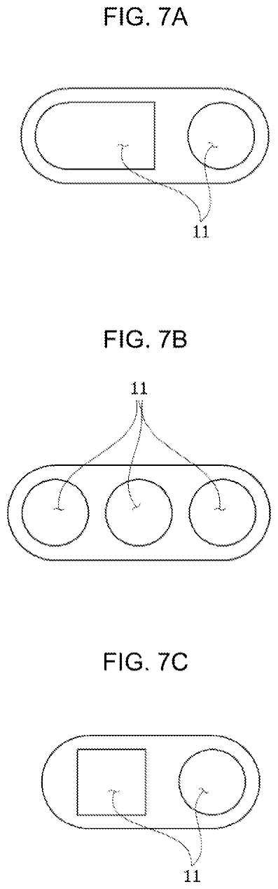

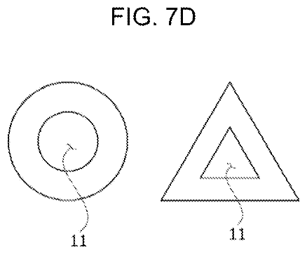

FIG. 6 is a view illustrating a shape in which the etch-stop layer surrounds the light-transmitting area. FIGS. 7A to 7D are views illustrating various shapes of the light-transmitting area.

Referring to FIG. 6, the first etch-stop layer ES1 may be disposed to entirely surround the periphery of the first opening 11. In addition, the second etch-stop layer ES2 may be disposed to entirely surround an outer circumferential surface of the display panel.

According to the aspect, since the first etch-stop layer ES1 is disposed to entirely surround the periphery of the first opening 11 and the second etch-stop layer ES2 is disposed to entirely surround the outer circumferential surface of the display panel, an etchant may be prevented from penetrating into the panel in a case in which a through hole is formed inside the substrate simultaneously when a mother substrate is cut.

Referring to FIGS. 7A to 7D, various shapes of the first opening 11 may be formed in the glass substrate 10 using wet etching. Thus, compared to conventional scribing, breaking, and grinding techniques, it is advantageous to form various openings while maintaining the rigidity of the substrate. In addition, it is advantageous to form the first opening 11 simultaneously when processing a side surface of the substrate 10 to form notches or recesses on the side surface of the substrate 10.

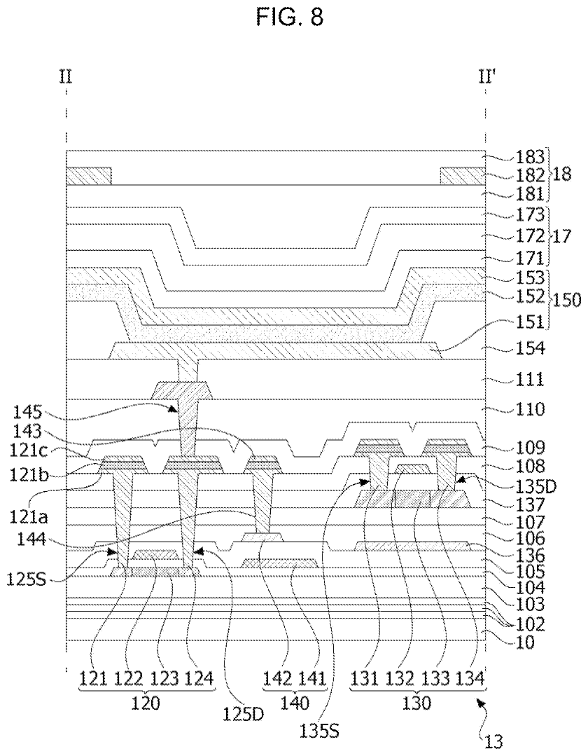

FIG. 8 is a view illustrating a cross section of the display area.

Referring to FIG. 8, the display area DA may include the substrate 10, a multi-buffer layer 102, and an active buffer layer 103, and a first transistor 120 may be disposed on the active buffer layer 103.

A lower gate insulating film 104 for insulating a first semiconductor layer 123 and a first gate electrode 122 may be disposed on the first semiconductor layer 123, wherein the first semiconductor layer 123 and the first gate electrode 122 constitute the first transistor 120. A first lower interlayer insulating film 105 and a second lower interlayer insulating film 106 may be sequentially disposed on the first gate electrode 122, and an upper buffer layer 107 may be disposed thereon.

The multi-buffer layer 102 may prevent the diffusion of moisture or oxygen into the substrate 10 and may be formed by alternately stacking silicon nitride (SiNₓ) and silicon oxide (SiOₓ) at least one time.

The active buffer layer 103 protects the first semiconductor layer 123 and may block various types of defects from being introduced into the substrate 10. The active buffer layer 103 may be formed of inorganic insulating material such as an amorphous semiconductor layer (a-Si), silicon nitride (SiNₓ), silicon oxide (SiOₓ), and the like.

The first semiconductor layer 123 of the first transistor 120 may be formed of a polycrystalline semiconductor layer, and the first semiconductor layer 123 may have a channel region, a source region, and a drain region.

Since the polycrystalline semiconductor layer has a higher mobility as compared to an amorphous semiconductor layer and an oxide semiconductor layer, the polycrystalline semiconductor layer has low energy consumption and excellent reliability. Due to these advantages, the polycrystalline semiconductor layer may be used for a driving transistor.

The first gate electrode 122 may be disposed on the lower gate insulating film 104 and may be disposed to overlap the first semiconductor layer 123.

A second transistor 130 may be disposed on the upper buffer layer 107, and a light-blocking layer 136 may be disposed below an area corresponding to the second transistor 130.

The light-blocking layer 136 may be disposed on the first lower interlayer insulating film 105 of the area corresponding to the second transistor 130, and a second semiconductor layer 133 of the second transistor 130 may be disposed on the second lower interlayer insulating film 106 and the upper buffer layer 107 to overlap the light-blocking layer 136.

An upper gate insulating layer 137 for insulating a second gate electrode 132 and the second semiconductor layer 133 may be disposed on the second semiconductor layer 133.

An upper interlayer insulating film 108 may be disposed on the second gate electrode 132. The first gate electrode 122 and the second gate electrode 132 may be a single layer or multi-layer formed of any one of molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The first and second lower interlayer insulating films 105 and 106 may be formed of an inorganic film having a higher hydrogen particle content as compared to the upper interlayer insulating film 108. For example, the first and second lower interlayer insulating films 105 and 106 may be formed of silicon nitride (SiNₓ) that is formed by a deposition process using NH₃ gas, and the upper interlayer insulating film 108 may be formed of silicon oxide (SiOₓ). Hydrogen particles included in the first and second lower interlayer insulating films 105 and 106 may be diffused into the polycrystalline semiconductor layer during a hydrogenation process to fill voids in the polycrystalline semiconductor layer with hydrogen. Accordingly, the polycrystalline semiconductor layer may be stabilized, thereby preventing deterioration of characteristics of the first transistor 120.

After an activation and hydrogenation process of the first semiconductor layer 123 of the first transistor 120, the second semiconductor layer 133 of the second transistor 130 may be formed, and in this case, the second semiconductor layer 133 may be formed of an oxide semiconductor. Since the second semiconductor layer 133 is not exposed to a high-temperature atmosphere of the activation and hydrogenation process of the first semiconductor layer 123, damage to the second semiconductor layer 133 may be prevented, which may improve reliability.

After the upper interlayer insulating film 108 is disposed, a first source contact hole 125S and a first drain contact hole 125D may be formed to correspond to the source and drain regions of the first transistor, respectively, and a second source contact hole 135S and a second drain contact hole 135D may be formed to correspond to the source and drain regions of the second transistor 130, respectively.

The first source contact hole 125S and the first drain contact hole 125D may be formed in a continuous hole from the upper interlayer insulating film 108 to the lower gate insulating film 104, and the second source contact hole 135S and the second drain contact hole 135D may also be formed in the second transistor 130.

A first source electrode 121 and a first drain electrode 124, which correspond to the first transistor 120, and a second source electrode 131 and a second drain electrode 134, which correspond to the second transistor 130 may be formed simultaneously, thereby reducing the number of processes for forming the source and drain electrodes of each of the first transistor 120 and the second transistor 130.

The first source and drain electrodes 121 and 124 and the second source and drain electrodes 131 and 134 may be a single layer or multi-layer formed of any one of molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The first source and drain electrodes 121 and 124 and the second source and drain electrodes 131 and 134 may each have a three-layer structure, for example, the first source electrode 121 may include a first layer 121a, a second layer 121b, and a third layer 121c, and the other source and drain electrodes may have the same structure.

A storage capacitor 140 may be disposed between the first transistor 120 and the second transistor 130. The storage capacitor 140 may be formed by overlapping a storage lower electrode 141 and a storage upper electrode 142 with the first lower interlayer insulating film 105 interposed therebetween.

The storage lower electrode 141 is located on the lower gate insulating film 104, and may be formed of the same material and on the same layer as the first gate electrode 122. The storage upper electrode 142 may be electrically connected to a pixel circuit through a storage supply line 143. The storage upper electrode 142 may be formed of the same material and on the same layer as the light-blocking layer 136. The storage upper electrode 142 is exposed through a storage contact hole 144 that passes through the second lower interlayer insulating film 106, the upper buffer layer 107, the upper gate insulating layer 137, and the upper interlayer insulating film 108 and connected to the storage supply line 143.

The storage upper electrode 142 is separated from the light-blocking layer 136, but the storage upper electrode 142 and the light-blocking layer 136 may also be formed as an integrated body in which they are connected to each other. The storage supply line 143 may be formed of the same material and on the same plane as the first source and drain electrodes 121 and 124 and the second source and drain electrodes 131 and 134, so that the storage supply line 143 may be simultaneously formed by the same mask process as the first source and drain electrodes 121 and 124 and the second source and drain electrodes 131 and 134.

By depositing an inorganic insulating material such as SiNₓ or SiOₓ on an entire surface of the substrate 10 on which the first source and drain electrodes 121 and 124, the second source and drain electrodes 131 and 134, and the storage supply line 143 are formed, a protective film 109 may be formed.

A first planarization layer 110 may be formed on the protective film 109. Specifically, the first planarization layer 110 may be disposed by applying an organic insulating material such as an acrylic-based resin to an entire surface of the protective film 109.

After forming the protective film 109 and the first planarization layer 110, a contact hole exposing the first source electrode 121 or the first drain electrode 124 of the first transistor 120 may be formed through a photolithography process. A connection electrode 145 that is made of a material formed of Mo, Ti, Cu, AlNd, Al, Cr, or an alloy thereof may be disposed in an area of the contact hole exposing the first drain electrode 124.

A second planarization layer 111 may be disposed on the connection electrode 145, and a contact hole for exposing the connection electrode 145 is formed in the second planarization layer 111 so that a light-emitting element 150 can be formed and connected to the first transistor 120.

The light-emitting element 150 may include an anode 151 connected to the first drain electrode 124 of the first transistor 120, at least one light-emitting stack 152 formed on the anode 151, and a cathode 153 formed on the light-emitting stack 152.

The light-emitting stack 152 may include a hole injection layer, a hole transport layer, an emission layer, an electron transport layer, and an electron injection layer in a multi-layered structure in which a plurality of emission layers are overlapped. In some cases, a charge generation layer may be disposed between the emission layers. The emission layers may emit different colors for respective sub-pixels.

The anode 151 may be connected to the connection electrode 145 that is exposed through the contact hole passing through the second planarization layer 111. The anode 151 may be formed in a multi-layer structure including a transparent conductive film and an opaque conductive film having high reflective efficiency. The transparent conductive film may be made of a material with a relatively large work function value, such as indium-tin-oxide (ITO) or indium-zinc-oxide (IZO), and the opaque conductive film may be formed of a single-layer or multi-layer structure containing Al, Ag, Cu, Pb, Mo, Ti, or an alloy thereof

For example, the anode 151 may be formed in a structure in which a transparent conductive film, an opaque conductive film, and a transparent conductive film are sequentially stacked, or a transparent conductive film and an opaque conductive film are sequentially stacked.

The anode 151 may be disposed on the second planarization layer 111 to overlap a light-emitting area provided by a bank 154 as well as a pixel circuit area in which the first and second transistors 120 and 130 and the storage capacitor 140 are disposed, thereby increasing an emission area.

The light-emitting stack 152 may be formed by stacking a hole transport layer, an organic emission layer, and an electron transport layer on the anode 151 in this order or in a reverse order. Additionally, the light-emitting stack 152 may further include a charge generation layer and may include first and second light-emitting stacks facing each other with the charge generation layer therebetween.

The bank 154 may be formed to expose the anode 151. The bank 154 may be formed of an organic material such as photoacrylic, and may be formed of a translucent material, but it is not limited thereto, and may be formed of an opaque material to prevent light interference between sub-pixels.

The cathode 153 may be formed on an upper surface of the light-emitting stack 152 to face the anode 151 with the light-emitting stack 152 interposed therebetween. When the cathode 153 is applied to a top emission type organic light-emitting display device, a transparent conductive film may be formed by thinly forming indium-tin-oxide (ITO), indium-zinc-oxide (IZO), or magnesium-silver (Mg—Ag).

The encapsulation portion 17 may be formed on the cathode 153 to protect the light-emitting element 150. Due to organic properties of the light-emitting stack 152, a dark spot or a pixel shrinkage phenomenon may occur in the light-emitting element 150 by reacting with external moisture or oxygen. The encapsulation portion 17 may be disposed on the cathode 153 to block moisture or oxygen from permeating into the cathode 153.

The encapsulation portion 17 may include a first inorganic insulating film 171, a foreign material compensation layer 172, and a second inorganic insulating film 173.

The touch portion 18 may be disposed on the encapsulation portion 17. The touch portion 18 may include a first touch planarization layer 181, a touch electrode 182, and a second touch planarization layer 183. The first touch planarization layer 181 and the second touch planarization layer 183 may be disposed to remove a step difference at a point where the touch electrode 182 is disposed and to ensure that the touch electrode 182 is electrically well insulated.

According to aspects of the disclosure, by placing the first transistor 120 made of low-temperature polycrystalline silicone and the second transistor 130 made of oxide semiconductor in different layers, TFTs having different driving characteristics may be disposed in the display device 100. However, the present disclosure is not necessarily limited thereto, and only TFTs having the same driving characteristic may be used.

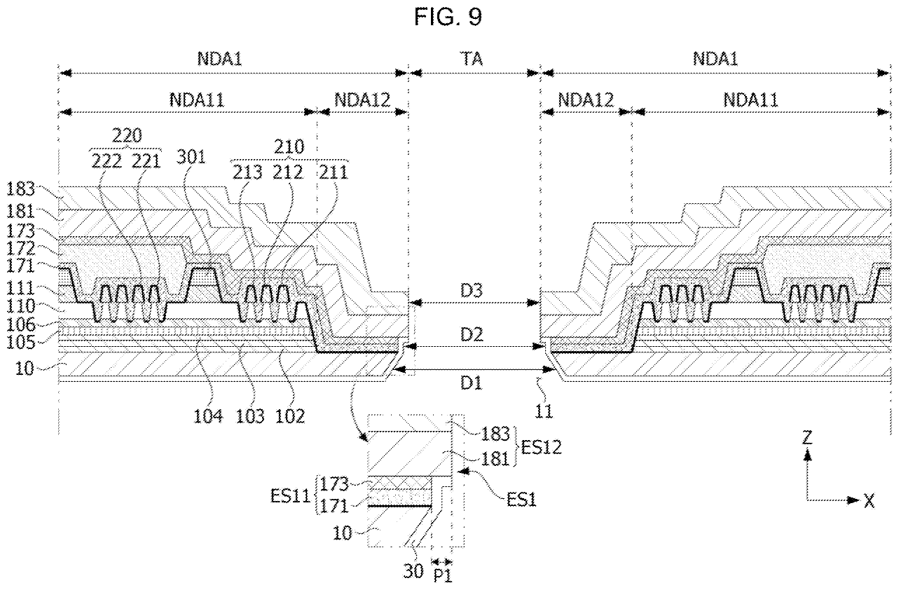

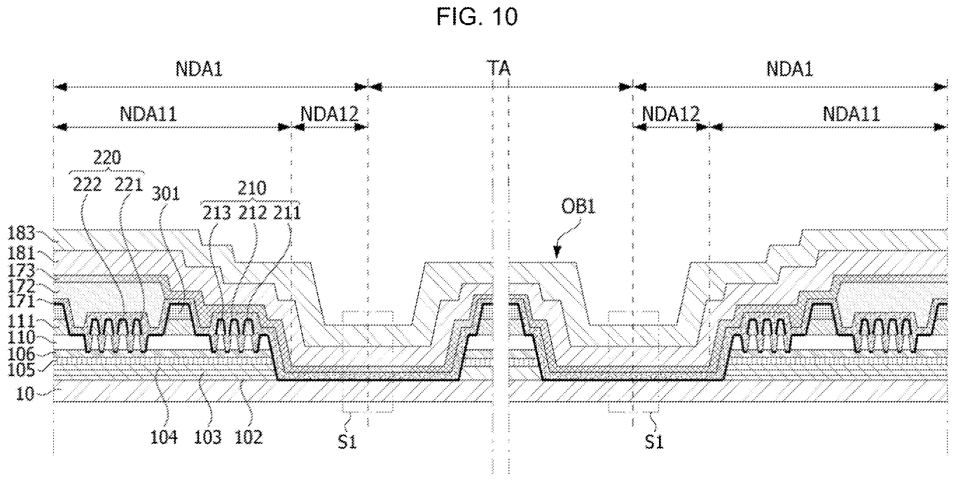

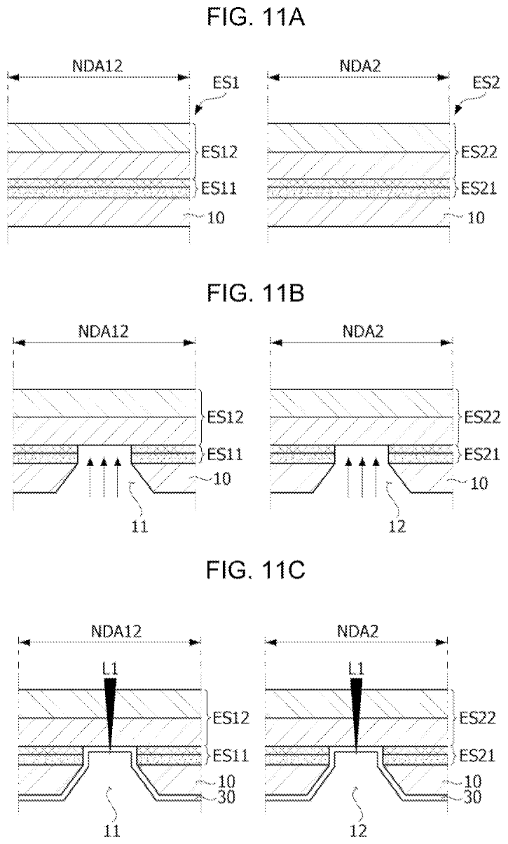

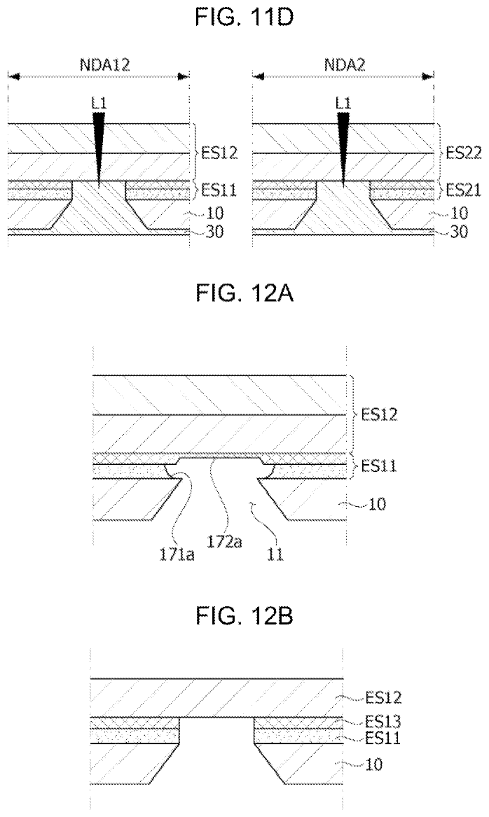

FIG. 9 is a view illustrating a display panel according to a first aspect of the present disclosure. FIG. 10 is a view illustrating the display panel before forming a light-transmitting area. FIGS. 11A to 11C are views illustrating a process of etching a substrate to form the light-transmitting area in the display panel.

Referring to FIG. 9, a first non-display area NDA1 may be disposed to surround a light-transmitting area TA. In addition, the first non-display area NDA1 may include a bezel area NDA11, in which a plurality of dam portions and a plurality of prevention portions are alternately disposed, and a dummy area NDA12 disposed between the bezel area NDA11 and the light-transmitting area TA.

In the bezel area NDA11, dam portions and prevention portions may be formed using a plurality of layers extending from a display area DA.

As an example, a first prevention portion 210 may include a first structure 211, a second structure 212, and a third structure 213, and a second prevention portion 220 may include a fifth structure 221 and a sixth structure 222. However, the number of the dams and the structures of the prevention portions may be varied.

A first dam 301, the first prevention portion 210, and the second prevention portion 220 may be disposed in a closed loop shape surrounding the light-transmitting area TA. Based on this configuration, moisture may be prevented from penetrating into the display area DA through the light-transmitting area TA.

The dummy area NDA12 may be an area formed to create a margin during laser cutting. Without the dummy area NDA12, the bezel area NDA11 may be damaged during laser cutting and thus vulnerable to moisture penetration. The dummy area NDA12 may have only minimal layers disposed on a substrate 10 to facilitate laser cutting.

In the aspect, an etch-stop layer may be an organic film, an inorganic film, or a metal layer disposed in the dummy area NDA12. That is, the organic film, the inorganic film, and the metal layer formed in the display area DA and the non-display area NDA may also be formed in the dummy area NDA12 and serve as the etch-stop layer. Accordingly, the same layer may have different reference numerals depending on the area in which the layer is disposed.

In the present disclosure, the etch-stop layer may include a plurality of sub-layers. Etch-stop performances of the plurality of sub-layers may be different. As an example, the sub-layer formed of an inorganic material may be etched by an etchant over time, while the sub-layer formed of an organic material or a metal may have faster etch-stop performance as compared to the sub-layer formed of the inorganic material.

In the present aspect, a first sub-layer ES11 may be formed by extending a first inorganic insulating film 171 and the second inorganic insulating film 173 of an encapsulation portion, and a second sub-layer ES12 may be formed by extending a first touch planarization layer 181 and a second touch planarization layer 183 of a touch portion. However, this is exemplary, and various inorganic films and various insulating films in the display area DA may be used as the etch-stop layer.

The light-transmitting area TA may include a first light-transmitting area D1 defined by a first opening 11 of the substrate 10, a second light-transmitting area D2 defined by the first sub-layer ES11, and a third light-transmitting area D3 defined by the second sub-layer ES12.

The first light-transmitting area D1 formed by the first opening 11 of the substrate may be formed to have a width that gradually narrows in an upward direction, and the third light-transmitting area D3 may be formed to have a width that is less than the minimum width of the first light-transmitting area D1. In addition, the second light-transmitting area D2 may have a width that is greater than the width of the third light-transmitting area D3. However, the present disclosure is not necessarily limited thereto, the first to third light-transmitting areas D1, D2, and D3 may have the same width when the first opening 11 is entirely filled with a coating layer 30 (see FIG. 5A).

According to the aspect, the substrate 10 is etched using an etchant, while a first etch-stop layer ES1 is cut using a laser, and thus the light-transmitting area TA may vary in width in a thickness direction. In addition, the first etch-stop layer ES1 exposed to an upper portion of the first opening 11 is cut by a laser, and a portion of the first etch-stop layer ES1 may remain on an inner side of the first opening 11 to form a protrusion P1.

Referring to FIG. 10, a dummy dam structure OB1 may be formed in an area in which the light-transmitting area TA is to be formed. Thus, in a lower side of the substrate 10, a rear surface of the substrate 10 is etched to remove the dummy dam structure OB1 of the light-transmitting area TA, and in an upper side of the substrate 10, the dummy dam structure OB1 may be removed by cutting the first etch-stop layer surrounding the dummy dam structure OB1 with a laser, thereby forming the light-transmitting area TA. At this time, a position 51 for etching the rear surface of the substrate 10 and a position 51 for cutting the first etch-stop layer with a laser may be the same.

Referring to FIG. 11A, the first etch-stop layer ES1 including the first sub-layer ES11 and the second sub-layer ES12 may be disposed on the substrate 10 in the dummy area NDA12. In addition, a second etch-stop layer ES2 including a first sub-layer ES21 and a second sub-layer ES22 may be disposed in a second non-display area NDA2, which is an edge of the substrate 10. The structure of the first etch-stop layer ES1 and the structure of the second etch-stop layer ES2 may be the same, but are not necessarily limited thereto, and may be different from each other.

Referring to FIG. 11B, when the rear surface of the substrate 10 in the dummy area NDA12 is exposed to an etchant, a portion not covered by a mask may be etched by the etchant. When the substrate 10 is etched, the etchant may come into contact with the first sub-layer ES11, and the first sub-layer ES11 may be etched over time. In the second non-display area NDA2, the first sub-layer ES21 may be etched in the same manner.

Referring to FIG. 11C, the coating layer 30 may be formed on the rear surface of the substrate 10. At this time, the coating layer 30 may be entirely formed on the inner side of the first opening 11 formed in the dummy area NDA12 and an inner side of a second opening 12 disposed in the second non-display area NDA2. Thereafter, the first etch-stop layer ES1 and the second etch-stop layer ES2 may be cut by irradiating a laser Ll. Thus, a plurality of panels may be separated from a mother substrate while forming the light-transmitting area TA in each display panel.

At this time, since the first sub-layer ES11, which is an inorganic material, has already been removed at the laser irradiation position, a phenomenon in which cracks propagate to the inorganic film during laser cutting may be improved.

Referring to FIG. 11D, the coating layer 30 may be entirely formed inside the first opening 11 and the second opening 12. Accordingly, cross sections cut through the first opening 11 and the second opening 12 may be straight and flat. Accordingly, the width of the light-transmitting area TA may be constant in the thickness direction.

Referring to FIG. 12A, the first sub-layer ES11 formed of an inorganic film may vary in shape depending on a thickness of the inorganic film or an etching time. As an example, a width by which a lower layer 171a of the first sub-layer ES11 is etched may be greater than a width by which an upper layer 172a of the first sub-layer ES11 is etched. In addition, a portion of the upper layer 172a of the first sub-layer ES11 may not be etched.

Referring to FIG. 12B, the etch-stop layer may include the sub-layer composed of a metal film in addition to the inorganic film and the organic film.

As an example, the first sub-layer ES11 may be composed of an inorganic material, the second sub-layer ES12 may be composed of a metal, and the third sub-layer ES13 may be composed of an organic material. Each sub-layer may be formed together when forming a plurality of layers in the display area DA.

As an example, the first sub-layer ES11 may be formed simultaneously when inorganic films such as a buffer layer, a gate insulating film, and a planarization layer are formed in the display area DA. The second sub-layer ES12 may be formed simultaneously when various metal layers, such as a gate electrode and an anode, are formed. In addition, the third sub-layer ES13 may be formed simultaneously when organic films, such as a planarization layer, a bank, a spacer, and an encapsulation portion 17 covering source/drain electrodes are formed.

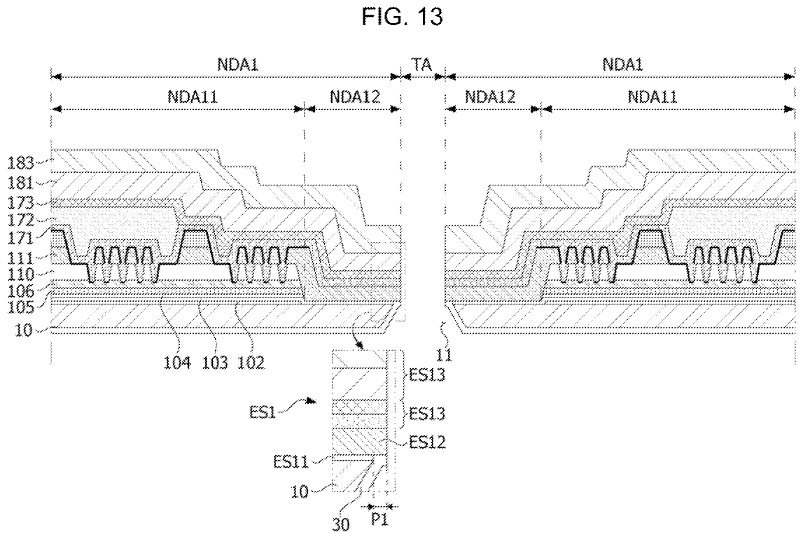

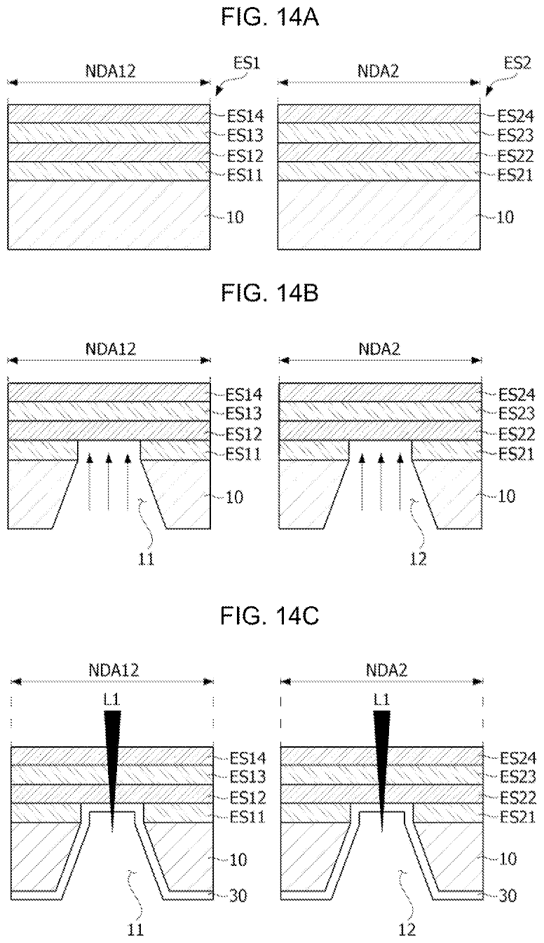

FIG. 13 is a view illustrating a display panel according to a second aspect of the present disclosure. FIGS. 14A to 14C are views illustrating a process of etching a substrate to form a light-transmitting area in the display panel.

Referring to FIG. 13, in the present aspect, a first sub-layer ES11 of a first etch-stop layer ES1 may be formed by extending an inorganic film such as an active buffer layer, a second sub-layer ES12 may be formed by extending an organic film such as a first or second planarization layer or a bank layer, a third sub-layer ES13 may be formed by extending a first or second inorganic insulating film of an encapsulation portion, and a fourth sub-layer ES14 may be formed by extending an organic film such as a first or second touch planarization layer of a touch portion.

Based on this configuration, a stacked structure of first inorganic film/first organic film/second inorganic film/second organic film may be obtained, and thus an etch-stop effect may be further improved. However, the present disclosure is not necessarily limited thereto, and the first etch-stop layer ES1 may have only a structure of inorganic film/organic film.

Referring to FIG. 14A, the first sub-layer ES11, the second sub-layer ES12, the third sub-layer ES13, and the fourth sub-layer ES14 may be sequentially stacked on a substrate in a dummy area NDA12. As described above, the first sub-layer ES11 may be an organic film, the second sub-layer ES12 may be an inorganic film, the third sub-layer ES13 may be an organic film, and the fourth sub-layer ES14 may be an inorganic film. A second etch-stop layer ES2 disposed in a second non-display area NDA2 may also have the same layer structure.

Referring to FIG. 14B, when a rear surface of the substrate 10 is exposed to an etchant, a portion thereof not covered by a mask may be etched by the etchant. When the substrate 10 is etched, the etchant may contact the first sub-layer ES11, and the first sub-layer ES11 may be etched over time.

Referring to FIG. 14C, a coating layer 30 may be formed on the rear surface of the substrate 10. In this case, the coating layer 30 may also be formed on an inner side of a first opening 11 formed in the substrate 10. Thereafter, the etch-stop layers may be cut by irradiating a laser. Based on this configuration, a cut surface of the etch-stop layer is relatively vertical, while the first opening 11 of the substrate 10 has a tapered shape. In addition, the second sub-layer ES12, the third sub-layer ES13, and the fourth sub-layer ES14 may protrude relatively toward an inner side of the first opening 11.

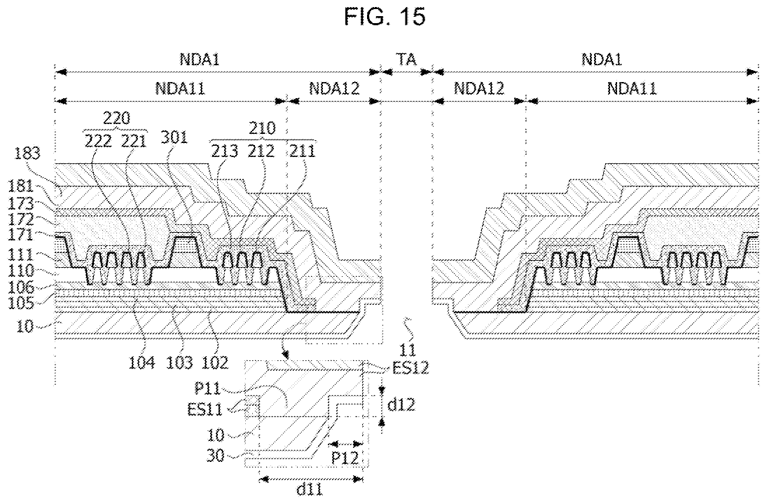

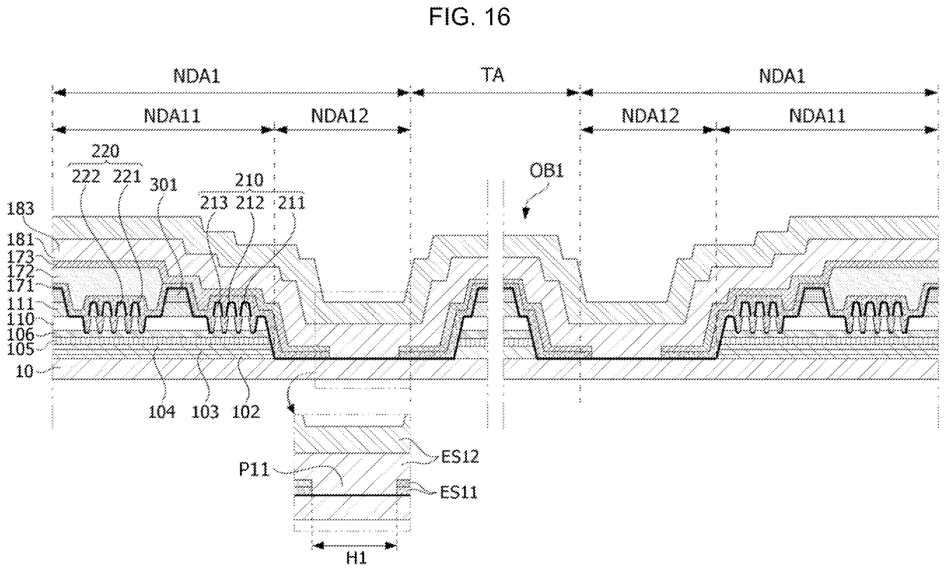

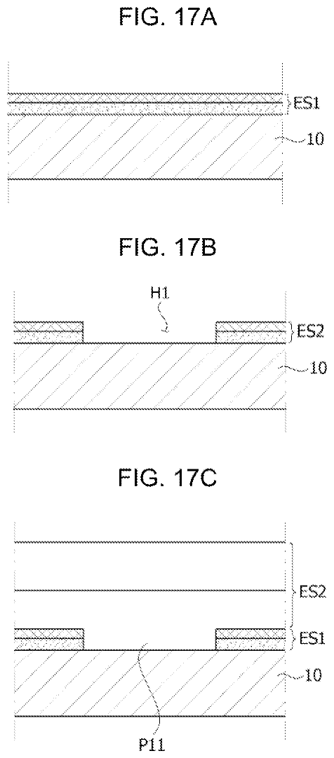

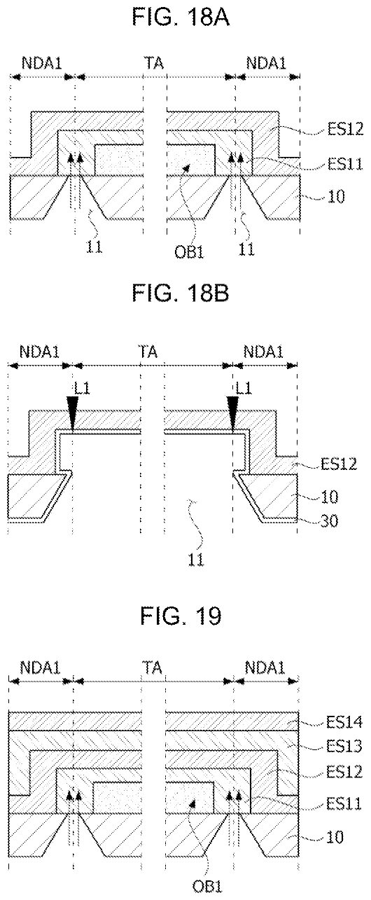

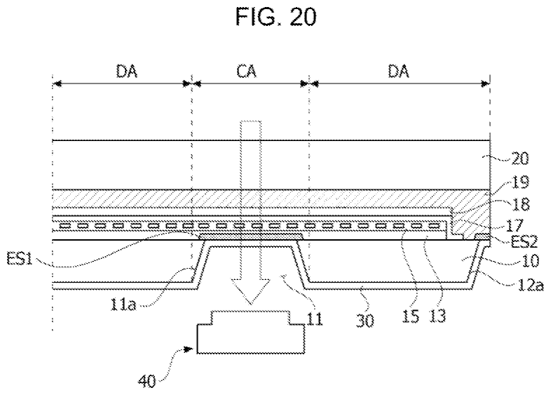

FIG. 15 is a view illustrating a display panel according to a third aspect of the present disclosure. FIG. 16 is a view illustrating the display panel before forming a light-transmitting area. FIGS. 17A to 17C are views illustrating a process of forming an etch-stop layer in a dummy area. FIGS. 18A and 18B are views illustrating a process of etching a substrate to form the light-transmitting area in the display panel. FIG. 19 is a modified example of FIG. 18A.

Referring to FIG. 15, a first non-display area NDA1 may be disposed to surround a light-transmitting area TA. In addition, the first non-display area NDA1 may include a bezel area NDA11 in which a plurality of dam portions and a plurality of prevention portions are alternately disposed, and a dummy area NDA12 disposed between the bezel area NDA11 and the light-transmitting area TA.

In the bezel area NDA11, the dam portions and the prevention portion may be formed by patterning a plurality of organic and inorganic films extending from a display area DA.

As an example, a first prevention portion 210 may include a first structure 211, a second structure 212, and a third structure 213, and a second prevention portion 220 may include a fifth structure 221 and a sixth structure 222.

A first dam 301, the first prevention portion 210, and the second prevention portion 220 may be disposed in a closed loop shape surrounding the light-transmitting area TA. With this configuration, moisture may be prevented from penetrating into the display area DA through the light-transmitting area TA.

In the present aspect, a first sub-layer ES11 may be formed by extending a first inorganic insulating film and a second inorganic insulating film of an encapsulation portion, and a second sub-layer ES12 may be formed by extending a first touch planarization layer and a second touch planarization layer of a touch portion. However, the present disclosure is not necessarily limited thereto, the first sub-layer ES11 may be formed of only one of the first inorganic insulating film and the second inorganic insulating film of the encapsulation portion. In addition, the second sub-layer ES12 may be formed of only one of the first touch planarization layer and the second touch planarization layer of the touch portion.

The first sub-layer ES11 may be formed only in a partial area of the dummy area NDA12. That is, the first sub-layer ES11 may be disposed to be separated from the light-transmitting area TA by a predetermined interval. On the other hand, the second sub-layer ES12 may extend to the light-transmitting area TA. That is, a separation distance d11 between the first sub-layer ES11 and the light-transmitting area TA may be greater than a separation distance between the second sub-layer ES12 and the light-transmitting area TA.

The second sub-layer ES12 may include a first protrusion P11 protruding from an end of the first sub-layer ES11 toward a substrate 10 and a second protrusion P12 protruding from the first protrusion P11 toward a first opening 11 of the substrate 10.

Here, a height of the second protrusion P12 may be formed to be higher than an upper surface of the substrate 10. A separation distance d12 between the second protrusion P12 and the upper surface of the substrate 10 in a vertical direction may be equal to a thickness of the first sub-layer ES11.

A coating layer 30 may be formed on a lower surface of the second protrusion P12. The coating layer 30 may be formed to a predetermined thickness in the first opening 11 of the substrate 10 and the lower surface of the second protrusion P12. However, the present disclosure is not necessarily limited thereto, the coating layer 30 may be filled entirely in the first opening 11.

Referring to FIG. 16, the first sub-layer ES11 may include a portion that is cut to form an insertion groove H1 in the dummy area NDA12, while the second sub-layer ES12 may be formed continuously from the bezel area NDA11 to the light-transmitting area TA. Thus, the first protrusion P11 corresponding to the insertion groove H1 may be formed in the second sub-layer ES12. The first protrusion P11 may be formed in a closed loop to surround a dummy dam structure OB1 of the light-transmitting area TA.

Referring to FIGS. 17A to 17C, after forming the first sub-layer ES11 on the substrate 10 in the dummy area as shown in FIG. 17A, a portion of the first sub-layer ES11 may be removed to form the insertion groove H1 as shown in FIG. 17B. Thereafter, when the second sub-layer ES12 is formed on the first sub-layer ES11, as shown in FIG. 17C, a portion of the second sub-layer ES12 may be inserted into the insertion groove H1. Thus, the second sub-layer ES12 may be inserted into the insertion groove H1 to form the first protrusion P11 in contact with the substrate 10.

Referring to FIG. 18A, the first sub-layer ES11 may be disposed to surround the dummy dam structure OB1, and the second sub-layer ES12 may be disposed to surround the first sub-layer ES11.

The first opening 11 may be formed in a rear surface of the substrate 10 to remove the dummy dam structure OB1. The first opening 11 may be formed to surround the dummy dam structure OB1. As an example, on the rear surface of the substrate 10, a mask may be formed on the remaining areas except for an area in which the first opening 11 is to be formed, and then the rear surface of the substrate 10 may be in contact with an etchant.

The second sub-layer ES12 may have the first opening 11 formed in the rear surface of the substrate 10 so that the first sub-layer ES11, which is an inorganic film, may be exposed to the etchant.

Referring to FIG. 18B, after a predetermined time has passed, the first sub-layer ES11 may be etched by the etchant. In contrast, the second sub-layer ES12, which is an organic film, resists the etch and may not be etched by the etchant over time. Thus, in the light-transmitting area TA, the dummy dam structure OB1 surrounded by the first sub-layer ES11 may be removed.

Thereafter, the coating layer 30 may be formed on an inner side surface of the first opening 11 of the substrate 10 and an inner surface of the second sub-layer ES12. The coating layer 30 may be entirely filled inside the first opening 11.

Thereafter, the second sub-layer ES12 may be cut using a laser L1 to form the light-transmitting area TA.

Referring to FIG. 19, the etch-stop layer may be formed by stacking a plurality of layers including an organic film, an inorganic film, and a metal film. As an example, the first sub-layer ES11 may be formed of an inorganic film, the second sub-layer ES12 may be formed of an organic film, a third sub-layer ES13 may be formed of an inorganic film, and a fourth sub-layer ES14 may be formed of an organic film.

In addition, the first sub-layer ES11 may be formed of an inorganic film, the second sub-layer ES12 may be formed of a metal film, and the third sub-layer ES13 and the fourth sub-layer ES14 may be formed of an organic film.

FIG. 20 is a conceptual diagram of a display device according to another aspect of the present disclosure.

Referring to FIG. 20, in the display device according to the aspect, an entire surface of a display panel may be configured as a display area DA. Thus, a full-screen display may be possible. The display device may be the display panel itself, or may be a concept including the display panel and a driving portion.

The display area DA may include a first display area DA and a second display area CA. The first display area DA and the second display area CA may each output an image but may be different in resolution. As an example, a resolution of a plurality of second pixels disposed in the second display area CA may be lower than a resolution of a plurality of first pixels disposed in the first display area DA. A large amount of light may be injected into a sensor 40 that is disposed in the second display area CA that is proportional to a resolution of second pixels disposed in the second display area CA.

However, the present disclosure is not necessarily limited thereto, and the resolution of the first display area DA and the resolution of the second display area CA may be the same when the second display area CA comprises sufficient light transmittance or an appropriate compensation algorithm.

The second display area CA may be an area in which the sensor 40 is disposed. The second display area CA is an area that overlaps various sensors and thus may be smaller in area than that of the first display area DA outputting most of the image.

The sensors 40 may include at least one of an image sensor, a proximity sensor, an illumination sensor, a gesture sensor, a motion sensor, a fingerprint recognition sensor, and a biometric sensor. As an example, a first sensor may be an illumination sensor or an infrared sensor and a second sensor may be a camera configured to capture an image or a video, but the present disclosure is not necessarily limited thereto.

A pixel array of the first display area DA may include a pixel area in which a plurality of pixel groups having a high pixel density or a higher pixels per inch (PPI) are disposed. A pixel array of the second display area CA may include a pixel area in which a plurality of pixel groups having a lower pixel density are disposed by being separated from each other by light-transmitting areas. In the second display area CA, external light may pass through the display panel through the light-transmitting areas having a high light transmittance and may be received by a sensor placed below the display panel.

A substrate 10 may include a first opening 11 disposed in the second display area CA. The first opening 11 may have a tapered shape that narrows in width as it approaches a cover glass 20. However, the first opening 11 is not necessarily limited thereto, and may be wider as it approaches the cover glass 20 or may be constant in width in a thickness direction. The tapered shape of the first opening 11 may be variously changed by the type of an etchant used and an etching method.

A first etch-stop layer ES1 may be disposed on the first opening 11 of the substrate 10. In addition, a second etch-stop layer ES2 may be disposed on an edge of the substrate 10. The first etch-stop layer ES1 and the second etch-stop layer ES2 may prevent an etchant from penetrating into the panel when etching the substrate 10.

The first etch-stop layer ES1 and the second etch-stop layer ES2 may include an organic material that is resistant to an etchant. As an example, the etch-stop layer may include one selected from the group consisting of a polyester-based polymer, a silicone-based polymer, an acrylic-based polymer, a polyolefin-based polymer, and a copolymer thereof

The first etch-stop layer ES1 and the second etch-stop layer ES2 may be formed by extending from at least one of layers constituting a circuit portion 13, an element portion 15, an encapsulation portion 17, and a touch portion 18. Based on this configuration, the etch-stop layer may be formed without adding a separate process.

A coating layer 30 may be formed on a rear surface of the substrate 10. The coating layer 30 may be formed of an organic material including, for example, a polyester-based polymer or an acrylic-based polymer.

A second non-display area NDA2 may be disposed on an edge of the display panel. The second non-display area NDA2 may comprise a margin portion that is required to separate a plurality of panels from a mother substrate.

The substrate 10 may include a second inclined surface 12a formed at the edge thereof. The second inclined surface 12a may have the same angle and the same depth as a first inclined surface 11 a formed in the first opening 11. The first opening 11 and the second inclined surface 12a are formed simultaneously by an etchant, so that the first opening 11 and the second inclined surface 12a may have the same inclination angle and etching depth.

According to the aspect, the first opening 11 may be formed in the substrate 10 of each display panel while separating a plurality of display panels by etching a mother substrate using an etchant. Thus, a light-transmitting efficiency may be improved by forming the opening without reducing the rigidity and without additional equipment.

According to an aspect, there is an advantage in that holes and other various shapes may be formed in a panel at the same time when a mother substrate is cut.

In addition, a case in which an etchant penetrates into a panel when etching a glass substrate may be prevented.

Effects of the present disclosure will not be limited to the above-mentioned effects and other unmentioned effects will be clearly understood by those skilled in the art from the following claims.

What is claimed is:

1. A display panel comprising:
a glass substrate including a display area and a light-transmitting area;
a circuit portion disposed in the display area; and
a light emitting portion disposed on the circuit portion and configured to emit light,
wherein the glass substrate includes a first opening disposed at a position corresponding to the light-transmitting area, and
the display panel includes a first etch-stop layer disposed on the glass substrate and surrounding the first opening, wherein the light-transmitting area is configured to pass light incident to the display through the display panel.

2. The display panel of claim 1, wherein the first etch-stop layer includes a protrusion protruding toward an inner side of the first opening.

3. The display panel of claim 2, comprising a coating layer formed on a rear surface of the glass substrate, an inner side surface of the first opening, and a lower surface of the protrusion.

4. The display panel of claim 2, wherein an inclination angle of an inner side surface of the first opening and an inclination angle of a side surface of the protrusion are different from each other.

5. The display panel of claim 1, wherein the first etch-stop layer includes an organic material.

6. The display panel of claim 1, wherein the glass substrate includes a second inclined surface formed at an edge, and
an angle of the second inclined surface is equal to an inclination angle of an inner side surface of the first opening.

7. The display panel of claim 6, comprising a second etch-stop layer disposed on the second inclined surface,
wherein the first etch-stop layer and the second etch-stop layer have the same layer structure.

8. The display panel of claim 1, wherein the first etch-stop layer includes a first sub-layer disposed on the glass substrate, and a second sub-layer disposed on the first sub-layer,
wherein the first sub-layer includes an inorganic material, and
the second sub-layer includes an organic material.

9. The display panel of claim 8, wherein the first etch-stop layer includes a third sub-layer disposed between the first sub-layer and the second sub-layer,
wherein the third sub-layer includes a metal.

10. The display panel of claim 8, wherein the second sub-layer further protrudes toward an inner side of the first opening.

11. The display panel of claim 8, wherein the first sub-layer includes an insertion groove, and
the second sub-layer includes a first protrusion disposed in the insertion groove.

12. The display panel of claim 11, wherein the second sub-layer includes a second protrusion protruding toward an inner side of the first opening,
wherein the second protrusion is disposed to be higher than an upper surface of the glass substrate.

13. The display panel of claim 8, wherein the display area includes:
a buffer layer;
a semiconductor layer disposed on the buffer layer;
a gate insulating film disposed on the semiconductor layer;
a gate electrode disposed on the gate insulating film;
a first insulating film disposed on the gate electrode;
a source electrode and a drain electrode disposed on the first insulating film;
a planarization layer disposed on the source electrode and the drain electrode; and
a bank layer disposed on the planarization layer, and
the second sub-layer is formed by extending the planarization layer or the bank layer to the light-transmitting area.

14. The display panel of claim 13, wherein the first sub-layer is formed by extending the buffer layer to the light-transmitting area.

15. A display panel comprising:
a glass substrate including a display area and a light-transmitting area;
a circuit portion disposed in the display area; and
a light emitting portion disposed on the circuit portion and configured to emit light,
wherein the glass substrate includes a first opening disposed at a position corresponding to the light-transmitting area and a second inclined surface formed on a side surface,
wherein an inclination angle of an inner side surface of the first opening and an inclination angle of the second inclined surface are the same.

16. The display panel of claim 15, comprising:
a first etch-stop layer disposed on the first opening; and
a second etch-stop layer disposed on the second inclined surface.

17. The display panel of claim 16, wherein the first etch-stop layer and the second etch-stop layer have the same layer structure.

18. The display panel of claim 16, wherein the first etch-stop layer includes a protrusion protruding toward an inner side of the first opening.

19. A display device comprising:
a glass substrate including a display area and a light-transmitting area;
a circuit portion disposed in the display area;
a light emitting portion disposed on the circuit portion; and
an electronic device disposed below the light-transmitting area,
wherein the glass substrate includes a first opening disposed at a position corresponding to the light-transmitting area, and
the display device includes a first etch-stop layer disposed on the glass substrate and surrounding the first opening.

20. The display device of claim 19, wherein
the glass substrate includes a second inclined surface formed at an edge, and
an angle of the second inclined surface is equal to an inclination angle of the first opening.

21. The display device of claim 1, wherein the circuit portion comprises:
a first active device formed using an oxide semiconductor in a first layer; and
a second active device formed using a polycrystalline silicone in a second layer.

22. The display device of claim 15, wherein the second inclined surface formed on the side surface is formed based on laser ablation of a margin region of a mother substrate including the display device and an adjacent display device.
